(19) United States
(12) Patent Application Publication
(10) Pub. No.: US 2025/0125814 A1
(43) Pub. Date: Apr. 17, 2025

(54) PIPELINED ANALOG-TO-DIGITAL CONVERTER

(71) Applicant: Chongqing GigaChip Technology Co., Ltd., Chongqing (CN)

(72) Inventors: Tao LIU, Chongqing (CN); Jianan WANG, Chongqing (CN); Minming DENG, Chongqing (CN); Lu LIU, Chongqing (CN); Dongbing FU, Chongqing (CN); Zhengping ZHANG, Chongqing (CN); Zhou YU, Chongqing (CN); Xu WANG, Chongqing (CN); Guangbing CHEN, Chongqing (CN); Xuemei WU, Chongqing (CN); Xiaodan ZHOU, Chongqing (CN)

(73) Assignee: Chongqing GigaChip Technology Co., Ltd., Chongqing (CN)

(21) Appl. No.: 19/001,528

(22) Filed: Dec. 25, 2024

Related U.S. Application Data
(63) Continuation of application No. PCT/CN2022/116673, filed on Sep. 2, 2022.

(30) Foreign Application Priority Data
Aug. 5, 2022 (CN) 202210938386.5

(51) Int. Cl. H03M 1/46; H03M 1/12

(52) U.S. Cl. CPC H03M 1/466; H03M 1/1205

(57) ABSTRACT

In a pipelined analog-to-digital converter, at least one pipeline stage includes an N-bit sub-analog-to-digital conversion module, a first sub-digital-to-analog conversion module, a second sub-digital-to-analog conversion module, and a switched capacitor amplification module. The first sub-digital-to-analog conversion module and the second sub-digital-to-analog conversion module respectively receive and process 2^{N-1} digital signals, which correspondingly require 2*2^{N-1} switched capacitors. In a pipeline stage based on a structure of “N-bit sub-analog-to-digital conversion module+sub-digital-to-analog conversion module+subtractor+multiplier”, the non-inverting input and the inverting input of the differential input comparison are completely symmetrical, which correspondingly requires 2*2^{N} switched capacitors.

### CROSS REFERENCE TO RELATED APPLICATION

The present patent document is a continuation application of PCT Application Serial No. PCT/CN2022/116673, filed on Sep. 2, 2022, designating the United States, and claiming the priority to Chinese Application Serial No. 202210938386.5, filed on Aug. 5, 2022, and contents of both applications are herein incorporated by reference in their entirety for all purposes.

### TECHNICAL FIELD

The present application relates to the technical field of analog integrated circuits, and in particular to a pipelined analog-to-digital converter.

### BACKGROUND

A pipelined analog-to-digital converter (ADC) is one type of commonly used analog-to-digital converter structure. Pipelined analog-to-digital converter is to cascade multiple pipeline stages of low-precision and high-sampling-rate analog-to-digital converter (hereinafter referred to as pipeline stages) in sequence, and process the digital output of each pipeline stage according to a certain algorithm to obtain the final encoded output, thereby making it have the characteristics of high speed and high precision.

Each pipeline stage mainly includes a sub-analog-to-digital converter (Sub ADC), a sub-digital-to-analog converter (Sub DAC), a subtraction unit, and a multiplication unit. The sub-analog-to-digital converter quantizes and encodes the analog input signal to obtain a digital signal. The sub-digital-to-analog converter performs digital-to-analog conversion on the digital signal to obtain an analog output voltage. The result of subtracting the analog output voltage from the analog input signal is amplified to obtain a residual output signal. In contemporary mixed-signal integrated circuit design, the sub-digital-to-analog converter, the subtractor, and the multiplication unit are all implemented using switched capacitors, and this type of switched capacitor circuit is called a multiplying digital-to-analog converter (MDAC).

### SUMMARY

In an aspect of the present application, a pipelined analog-to-digital converter includes a plurality of pipeline stages cascaded in sequence, at least one of the pipeline stages includes: a N-bit sub-analog-to-digital conversion module to receive an analog input signal and perform analog-to-digital conversion on the analog input signal to obtain and output 2^{N} digital signals; a first sub-digital-to-analog conversion module to receive 2^{N-1} digital signals and perform digital-to-analog conversion on the 2^{N-1} digital signals to obtain and output a first analog signal; a second sub-digital-to-analog conversion module to receive other 2^{N-1} digital signals and perform digital-to-analog conversion on the other 2^{N-1} digital signals to obtain and output a second analog signal; and a switched capacitor amplification module to receive the first analog signal and the second analog signal, perform a difference operation on the first analog signal and the second analog signal, and perform an amplification operation on a result of the difference operation, to obtain and output an analog output signal, wherein N is an integer greater than or equal to 1.

In one or more embodiments of the present application, the N-bit sub-analog-to-digital conversion module includes: a first resistor divider unit to perform voltage division processing on an initial reference voltage and output 2^{N} non-inverting reference voltages to outside; a second resistor divider unit to perform voltage division processing on the initial reference voltage and output 2^{N} inverting reference voltages to the outside; and a comparator array unit connected to the first resistor divider unit and the second resistor divider unit, to receive the analog input signal and compare the analog input signal with 2^{N} reference voltages, respectively, to obtain 2^{N} digital signals, wherein the 2^{N} digital signals include 2^{N-1} first digital signals and 2^{N-1} second digital signals, wherein the 2^{N} non-inverting reference voltages correspond one-to-one to the 2^{N} inverting reference voltages to constitute the 2^{N} reference voltages.

In one or more embodiments of the present application, the first resistor divider unit includes a first input port, a second input port, and 2^{N}+1 first resistors, wherein the 2^{N}+1 first resistors are connected in series between the first input port and the second input port in sequence, the first input port is connected to a positive end of the initial reference voltage, the second input port is connected to a negative end of the initial reference voltage, and a common end of two adjacent first resistors outputs the non-inverting reference voltage.

In one or more embodiments of the present application, the second resistor divider unit includes a third input port, a fourth input port, and 2^{N}+1 second resistors, wherein the 2^{N}+1 second resistors are connected in series between the third input port and the fourth input port in sequence, the third input port is connected to a negative end of the initial reference voltage, the fourth input port is connected to a positive end of the initial reference voltage, and a common end of two adjacent second resistors outputs the inverting reference voltage.

In one or more embodiments of the present application, the comparator array unit includes: 2^{N} comparators to compare and quantize the analog input signal with the 2^{N} reference voltages one by one and output 2^{N}−1 first initial digital signals and 2^{N}−1 second initial digital signals; and 2^{N} drivers, wherein input ends of the 2^{N} drivers are connected to output ends of the 2^{N} comparators in a one-to-one correspondence, and the output ends of the 2^{N} drivers output the 2^{N}−1 first digital signals and the 2^{N}−1 second digital signals controlled by a first clock signal.

In one or more embodiments of the present application, the 2^{N} comparators are arranged in parallel; in an i-th comparator, a first input end of the comparator is connected to a positive end of the analog input signal, a second input end of the comparator is connected to a negative end of the analog input signal, a third input end of the comparator is connected to an i-th non-inverting reference voltage, and a fourth input end of the comparator is connected to an i-th inverting reference voltage, wherein i=1, 2, . . . , 2^{N}; the 2^{N} drivers are arranged in parallel; in an i-th said driver, a first input end of the driver is connected to a first output end of the i-th comparator, a second input end of the driver is connected to a second output end of the i-th comparator, and a third input end of the driver is connected to the first clock signal; and an output end of an m-th comparator outputs the first initial digital signal, an output end of an m-th driver outputs the first digital signal, an output end of an n-th comparator outputs the second initial digital signal, and an output end of an n-th driver outputs the second digital signal, wherein m is an odd number from 1 to 2^{N}, and n is an even number from 1 to 2^{N}.

In one or more embodiments of the present application, the driver includes a first NAND gate, a first NOR gate, a first NOT gate, a second NOT gate, and a third NOT gate, a first input end of the first NAND gate serves as the first input end of the driver, a second input end of the first NAND gate is connected to an output end of the first NOT gate, an output end of the first NAND gate is connected to an input end of the second NOT gate, an output end of the second NOT gate serves as a second output end of the driver, an input end of the first NOT gate serves as the third input end of the driver, a first input end of the first NOR gate is connected to the input end of the first NOT gate, a second input end of the first NOR gate serves as the second input end of the driver, an output end of the first NOR gate is connected to an input end of the third NOT gate, and an output end of the third NOT gate serves as a first output end of the driver.

In one or more embodiments of the present application, the first sub-digital-to-analog conversion module includes 2^{N-1} first switched capacitor units arranged in parallel, a first input end of a j-th first switched capacitor unit is connected to a second clock signal, a second input end of the j-th first switched capacitor unit is connected to the positive end of the analog input signal, a third input end of the j-th first switched capacitor unit is connected to the positive end of the initial reference voltage, a fourth input end of the j-th first switched capacitor unit is connected to the negative end of the initial reference voltage, a fifth input end of the j-th first switched capacitor unit is connected to a negative end of a j-th first digital signal, a sixth input end of the j-th first switched capacitor unit is connected to a positive end of the j-th first digital signal, and output ends of the 2^{N-1} first switched capacitor units are connected in parallel and output the first analog signal to the outside, wherein j=1, 2, . . . , 2^{N-1}; and the second sub-digital-to-analog conversion module includes 2^{N-1} second switched capacitor units arranged in parallel, a first input end of a j-th second switched capacitor unit is connected to the second clock signal, a second input end of the j-th second switched capacitor unit is connected to the negative end of the analog input signal, a third input end of the j-th second switched capacitor unit is connected to the positive end of the initial reference voltage, a fourth input end of the j-th second switched capacitor unit is connected to the negative end of the initial reference voltage, a fifth input end of the j-th second switched capacitor unit is connected to a positive end of a j-th second digital signal, a sixth input end of the j-th second switched capacitor unit is connected to a negative end of the j-th second digital signal, and output ends of the 2^{N-1} second switched capacitor units are connected in parallel and output the second analog signal to the outside.

In one or more embodiments of the present application, the first switched capacitor unit includes a first NMOS transistor, a second NMOS transistor, a first PMOS transistor, and a switched capacitor, a gate of the first NMOS transistor serves as a first input end of the first switched capacitor unit, a drain of the first NMOS transistor serves as a second input end of the first switched capacitor unit, a gate of the second NMOS transistor serves as a sixth input end of the first switched capacitor unit, a drain of the second NMOS transistor serves as a fourth input end of the first switched capacitor unit, a gate of the first PMOS transistor serves as a fifth input end of the first switched capacitor unit, a source of the first PMOS transistor serves as a third input end of the first switched capacitor unit, a source of the first NMOS transistor, a source of the second NMOS transistor, and a drain of the first PMOS transistor are respectively connected to one end of the switched capacitor, and the other end of the switched capacitor serves as an output end of the first switched capacitor unit.

In one or more embodiments of the present application, the switched capacitor amplification module includes a third NMOS transistor, a fourth NMOS transistor, a fifth NMOS transistor, a sixth NMOS transistor, a first capacitor, a second capacitor, and a fully differential operational amplifier, a gate of the third NMOS transistor, a gate of the fourth NMOS transistor, and a gate of the fifth NMOS transistor are respectively connected to a third clock signal, a drain of the third NMOS transistor and a drain of the fifth NMOS transistor are respectively connected to a basic signal, a source of the fifth NMOS transistor, a drain of the fourth NMOS transistor, a non-inverting input end of the fully differential operational amplifier, an output end of the first sub-digital-to-analog conversion module, and one end of the first capacitor are connected together, the other end of the first capacitor, an inverting output end of the fully differential operational amplifier, and the drain of the sixth NMOS transistor are connected together, a source of the third NMOS transistor, a source of the fourth NMOS transistor, an inverting input end of the fully differential operational amplifier, an output end of the second sub-digital-to-analog conversion module, and one end of the second capacitor are connected together, the other end of the second capacitor, a non-inverting output end of the fully differential operational amplifier, and a source of the sixth NMOS transistor are connected together, a gate of the sixth NMOS transistor is connected to a fourth clock signal, the non-inverting output end of the fully differential operational amplifier serves as a positive output end of the switched capacitor amplification module, and the inverting output end of the fully differential operational amplifier serves as a negative output end of the switched capacitor amplification module.

In one or more embodiments of the present application, a capacitance value of the first capacitor is equal to a capacitance value of the second capacitor.

### BRIEF DESCRIPTION OF DRAWINGS

FIG. 1 is a schematic diagram showing a structure of a pipeline stage of a pipelined analog-to-digital converter.

FIG. 2 is a circuit diagram showing a pipeline stage of a pipelined analog-to-digital converter according to one or more embodiments of the present application.

FIG. 3 is a circuit diagram of an N-bit sub-analog-to-digital conversion module 1 in FIG. 2.

FIG. 4 is a circuit diagram of a first resistor divider unit 11 in FIG. 3.

FIG. 5 is a circuit diagram of a second resistor divider unit 12 in FIG. 3.

FIG. 6 is a circuit diagram of a comparator array unit 13 in FIG. 3.

FIG. 7 is a circuit diagram of a driver in FIG. 6.

FIG. 8 is a circuit diagram of a first sub-digital-to-analog conversion module 2 in FIG. 2.

FIG. 9 is a circuit diagram of a second sub-digital-to-analog conversion module 3 in FIG. 2.

FIG. 10 is a circuit diagram of a first switched capacitor unit in FIG. 8.

FIG. 11 is a timing state diagram showing a first clock signal ϕ1, a second clock signal ϕ2, a third clock signal ϕ3, and a fourth clock signal ϕ4 in FIG. 2.

FIG. 12 is a schematic diagram showing a transmission curve of a pipeline stage of a pipelined analog-to-digital converter in FIG. 2.

### DESCRIPTION OF EMBODIMENTS

The following describes the embodiments of the present application through specific examples, and those skilled in the art can easily understand other advantages and effects of the present application from the contents disclosed in this specification. The present application can also be implemented or applied through other different specific embodiments, and the details in this specification can also be modified or changed in various ways based on different viewpoints and applications without departing from the spirit of the present application.

The typical implementation of the switched capacitor circuit is a switched capacitor DAC array, which is in a 2^{N} relationship with the resolution N. As the resolution N increases, the switched capacitor DAC array grows exponentially, resulting in a continuous increase in the cost of the area and the power consumption of the switched capacitor circuit, and the increase in capacitance will also limit the increase in speed.

Therefore, there is an urgent need for a simplified solution for the switched capacitor circuit in a pipelined analog-to-digital converter.

The present application provides a technical solution for a pipelined analog-to-digital converter, which may simplify the structure of the switched capacitor circuit in the pipelined analog-to-digital converter, reduce its area and power consumption, and improve its analog-to-digital conversion speed.

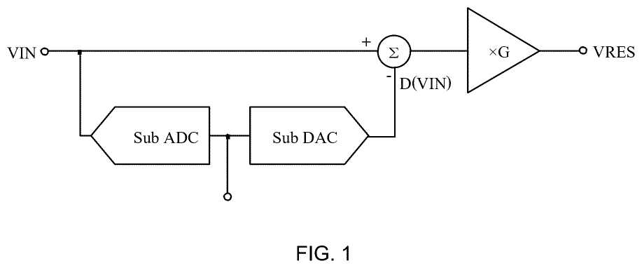

Please refer to FIGS. 1 to 12. It should be noted that the diagrams provided in these embodiments only illustrate the basic concept of the present application in a schematic manner, so the diagrams only show the components related to the present application rather than drawing them according to the number, shape, and size of the components during actual implementation. During actual implementation, the type, quantity, and scale of each component can be changed at will, and the component layout may also be more complicated. The structure, scale, size, etc. shown in the drawings attached to this specification are only used to match the content disclosed in the specification for people familiar with this technology to understand and read and have no technical substantive significance in terms of being used to limit the limiting conditions that the present application can be implemented. Any modification of the structure, change of the proportional relationship, or adjustment of the size should still fall within the scope of the technical content disclosed by the present application without affecting the effect that the present application can produce and the purpose that can be achieved.

As described above in the background chapter, after research the inventors have found that: the pipeline stage shown in FIG. 1 mainly includes a sub-analog-to-digital converter (Sub ADC), a sub-digital-to-analog converter (Sub DAC), a subtraction unit, and a multiplication unit. The sub-analog-to-digital converter quantizes and encodes an analog input signal VIN to obtain a digital signal, and the sub-digital-to-analog converter performs digital-to-analog conversion on a digital signal to obtain an analog output voltage D(VIN). The result of subtracting the analog output voltage D(VIN) from the analog input signal VIN is amplified by a factor of G to obtain a residual output signal VRES. The sub-digital-to-analog converter, the subtractor, and the multiplication unit are all implemented with switched capacitors, and this type of switched capacitor circuit is called a multiplying digital-to-analog converter (MDAC). A typical implementation method of a switched capacitor circuit is a switched capacitor array, and the switched capacitor array is in a 2^{N} relationship with the resolution N. As the resolution N increases, the switched capacitor array (especially the switched capacitor array corresponding to the sub-digital-to-analog converter, the sub-digital-to-analog converter in the pipeline stage with an N-bit resolution requires 2*2^{N} switched capacitors) grows exponentially, resulting in a continuous increase in the cost of area and power consumption of the switched capacitor circuit, and the increase in capacitance will also limit the increase in speed.

Based on this, the present application proposes a novel design scheme of a pipelined analog-to-digital converter in which, based on the pipeline structure of “N-bit sub-analog-to-digital conversion module+first sub-digital-to-analog conversion module+second sub-digital-to-analog conversion module+switched capacitor amplification module”, the digital output of the N-bit sub-analog-to-digital conversion module is split into two parts, the sub-digital-to-analog conversion module is correspondingly split into two parts, and two different sub-digital-to-analog conversion modules are controlled one-to-one through the two parts of digital output in the N-bit sub-analog-to-digital conversion module, so as to simplify the number of switched capacitors in the sub-digital-to-analog conversion module, reduce power consumption and improve processing speed.

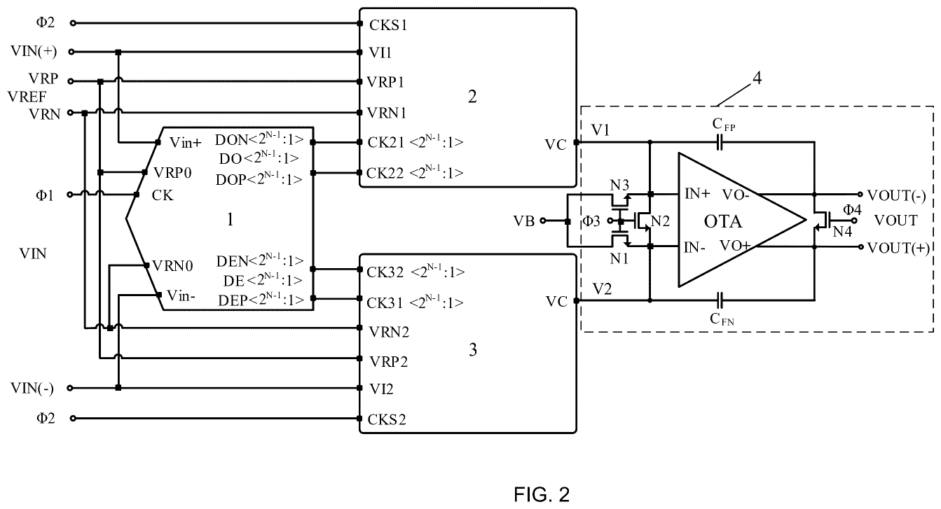

In one or more embodiments of the present application, the present application proposes a pipelined analog-to-digital converter, which includes a plurality of pipeline stages cascaded in sequence, as shown in FIG. 2, at least one pipeline stage includes: an N-bit sub-analog-to-digital conversion module 1 which receives an analog input signal VIN and performs analog-to-digital conversion on the analog input signal VIN to obtain and output 2^{N} digital signals, that is, 2^{N-1} first digital signals DO<2^{N-1}:1> and 2^{N-1} second digital signals DE<2^{N-1}:1>; a first sub-digital-to-analog conversion module 2 which receives 2^{N-1} digital signals (i.e., the first digital signal DO<2^{N-1}:1>) and performs digital-to-analog conversion on the 2^{N-1} digital signals to obtain and output a first analog signal V1; a second sub-digital-to-analog conversion module 3 which receives other 2^{N-1} digital signals (i.e., the second digital signal DE<2^{N-}1:1>) and performs digital-to-analog conversion on the other 2^{N-1} digital signals to obtain and output a second analog signal V2; and a switched capacitor amplification module 4 which receives the first analog signal V1 and the second analog signal V2, performs a difference operation on the first analog signal V1 and the second analog signal V2 and performs an amplification operation on the result of the difference operation to obtain and output an analog output signal VOUT, where N is an integer greater than or equal to 1.

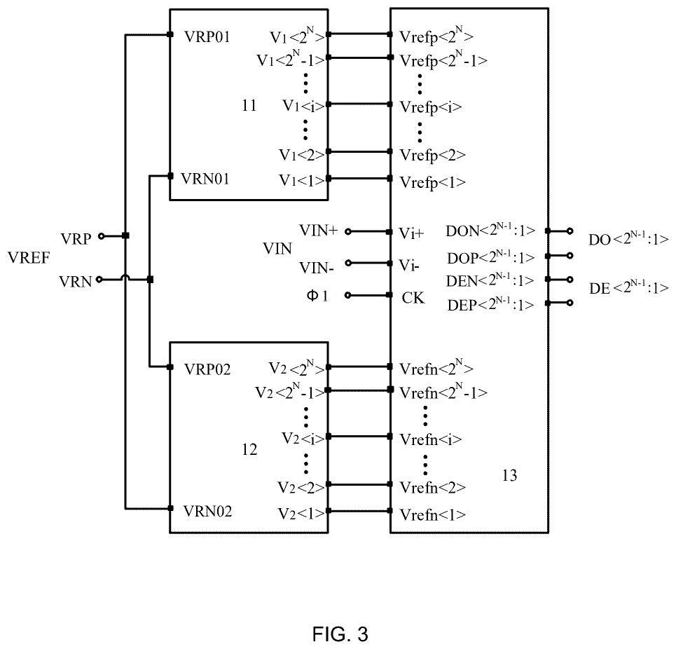

In one or more embodiments of the present application, as shown in FIG. 3, the N-bit sub-analog-to-digital conversion module 1 includes: a first resistor divider unit 11 which performs voltage dividing processing on an initial reference voltage VREF and outputs 2^{N} non-inverting reference voltages, that is, non-inverting reference voltage Vrefp<2^{N-1}:1>; a second resistor divider unit 12 performs voltage division processing on the initial reference voltage VREF and outputs 2^{N} inverting reference voltages, that is, inverting reference voltages Vrefn<2^{N-1}:1>; and a comparator array unit 13 which is connected to the first resistor divider unit 11 and the second resistor divider unit 12, respectively, receives the analog input signal VIN, and compares the analog input signal VIN with 2^{N} reference voltages to obtain 2^{N} digital signals, where the 2^{N} digital signals include 2^{N-1} first digital signals (i.e., first digital signals DO<2^{N-1}:1>) and 2^{N-1} second digital signals (i.e., second digital signals DE<2^{N-1}:1>), the 2^{N} non-inverting reference voltages correspond to the 2^{N} inverting reference voltages one by one to form 2^{N} reference voltages, i.e., the non-inverting reference voltage Vrefp<2^{N-1}> and the inverting reference voltage Vrefn<2^{N-1}> form a reference voltage, the non-inverting reference voltage Vrefp<2^{N-1}−1> and the inverting reference voltage Vrefn<2^{N-1}−1> form a reference voltage, . . . , the non-inverting reference voltage Vrefp<i> and the inverting reference voltage Vrefn<i> form a reference voltage, . . . , the non-inverting reference voltage Vrefp<2> and the inverting reference voltage Vrefn<2> form a reference voltage, the non-inverting reference voltage Vrefp<1> and the inverting reference voltage Vrefn<1> form a reference voltage, where i=1, 2, . . . , 2^{N}.

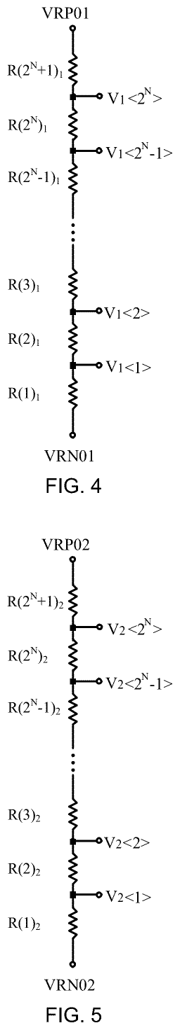

In one or more embodiments of the present application, as shown in FIG. 4, the first resistor divider unit 11 includes a first input port VRP01, a second input port VRN01 and 2^{N}+1 first resistors, that is, a first resistor R(1)₁, a first resistor R(2)₁, a first resistor R(3)₁, . . . , a first resistor R(2^{N-1})₁, a first resistor R(2^{N})₁, and a first resistor R(2^{N}+1)₁. The 2^{N}+1 first resistors are sequentially connected in series between the first input port VRP01 and the second input port VRN01, that is, the first resistor R(2^{N}+1)₁, the first resistor R(2^{N})₁, the first resistor R(2^{N}−1)₁, . . . , the first resistor R(3)₁, the first resistor R(2)₁, and the first resistor R(1)₁ are sequentially connected in series between the first input port VRP01 and the second input port VRN01. The first input port VRP01 is connected to a positive end VRP of the initial reference voltage VREF, the second input port VRN01 is connected to a negative end VRN of the initial reference voltage VREF, and a common end of two adjacent first resistors outputs a non-inverting reference voltage, that is, the common end V₁<1> of the first resistor R(2)₁ and the first resistor R(1)₁ outputs the non-inverting reference voltage Vrefp<1>, the common end V₁<2> of the first resistor R(3)₁ and the first resistor R(2)₁ outputs the non-inverting reference voltage Vrefp<2>, . . . , the common end V1<2^{N}−1> of the first resistor R(2^{N}−1)₁ and the first resistor R(2^{N})₁ outputs the non-inverting reference voltage Vrefp<2^{N}−1>, and the common end V₁<2^{N}> of the first resistor R(2^{N}+1)₁ and the first resistor R(2^{N})₁ outputs the non-inverting reference voltage Vrefp<2^{N}>.

In one or more embodiments of the present application, as shown in FIG. 5, the second resistor divider unit 12 includes a third input port VRP02, a fourth input port VRN02, and 2^{N}+1 second resistors, that is, a second resistor R(1)₂, a second resistor R(2)₂, a second resistor R(3)₂, . . . , a second resistor R(2^{N}−1)₂, a second resistor R(2^{N})₂, and a second resistor R(2^{N}+1)₂. The 2^{N}+1 second resistors are sequentially connected in series between the third input port VRP02 and the fourth input port VRN02, that is, the second resistor R(2^{N}+1)₂, the second resistor R(2^{N})₂, the second resistor R(2^{N}−1)₂, . . . , the second resistor R(3)₂, the second resistor R(2)₂, and the second resistor R(1)₂ are sequentially connected in series between the third input port VRP02 and the fourth input port VRN02, the third input port VRP02 is connected to the negative end VRN of the initial reference voltage VREF, the fourth input port VRN02 is connected to the positive end VRP of the initial reference voltage VREF, a common end of two adjacent second resistors outputs an inverting reference voltage, that is, the common end V₂<1> of the second resistor R(2)₂ and the second resistor R(1)₂ outputs the inverting reference voltage Vrefn<1>, the common end V₂<2> of the second resistor R(3)₂ and the second resistor R(2)₂ outputs the inverting reference voltage Vrefn<2>, . . . , the common end V₂<2^{N}−1> of the second resistor R(2^{N})₂ and the second resistor R(2^{N})₂ outputs the inverting reference voltage Vrefn<2^{N}−1>, the common end V₂<2^{N}> of the second resistor R(2^{N}+1)₂ and the second resistor R(2^{N})₂ outputs the inverting reference voltage Vrefn<2^{N}>.

In one or more embodiments of the present application, R(1)₁=R(2^{N}+1)₁, R(2)₁=R(3)₁= . . . =R(2^{N}−1)₁=R(2^{N})₁, and R(2)₁=2×R(1)₁; R(1)₂=R(2^{N}+1)₂, R(2)₂=R(3)₂= . . . =R(2^{N}−1)₂=R(2^{N})₂, and R(2)₂=2×R(1)₂.

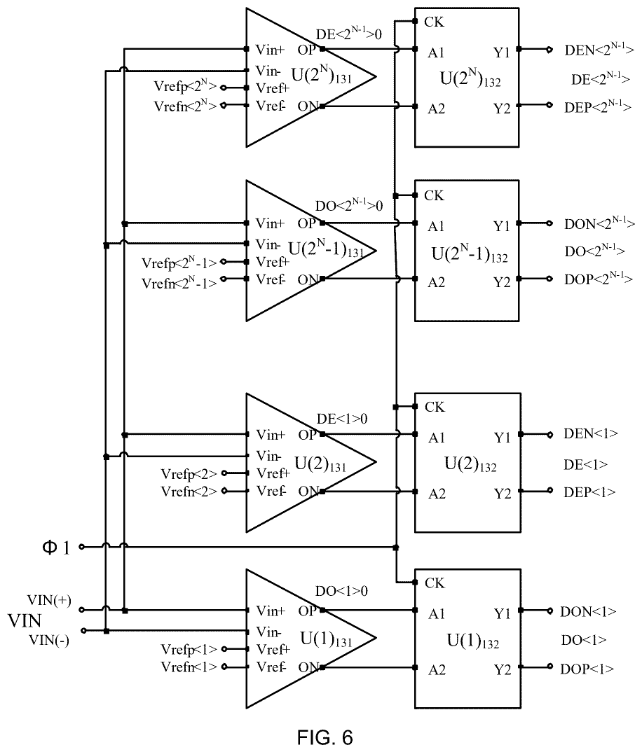

In one or more embodiments of the present application, as shown in FIG. 6, the comparator array unit 13 includes: 2^{N} comparators, i.e., comparator U(2^{N})₁₃₁, comparator U(2^{N}−1)₁₃₁, . . . , comparator U(2)₁₃₁, and comparator U(1)₁₃₁, which compare and quantize the analog input signal VIN with the 2^{N} reference voltages one by one, and output 2^{N-1} first initial digital signals (that is, first initial digital signals DO<2^{N}:1>0) and 2^{N-1} second initial digital signals (that is, second initial digital signals DE<2^{N}:1>0); and 2^{N} drivers, i.e., driver U(2^{N})₁₃₂, driver U(2^{N}−1)₁₃₂, . . . , driver U(2)₁₃₂, and driver U(1)₁₃₂, the input ends of the 2^{N} drivers are connected to the output ends of the 2^{N} comparators in a one-to-one correspondence, the input end of driver U(2^{N})₁₃₂ is connected to the output end of comparator U(2^{N})₁₃₁, the input end of driver U(2^{N}−1)₁₃₂ is connected to the output end of comparator U(2^{N}−1)₁₃₁, . . . , the input end of driver U(2)₁₃₂ is connected to the output end of comparator U(2)₁₃₁, the input end of driver U(1)₁₃₂ is connected to the output end of comparator U(1)₁₃₁, and the output ends of the 2^{N} drivers output 2^{N}−1 first digital signals (i.e., first digital signals DO<2^{N}:1>) and 2^{N}−1 second digital signals (i.e., second digital signals DE<2^{N}:1>) controlled by a first clock signal ϕ1 to the outside.

In one or more embodiments of the present application, as shown in FIG. 6, 2^{N} comparators are arranged in parallel. In the i-th comparator U(i)₁₃₁, a first input end Vin+ of the comparator is connected to the positive end VIN(+) of the analog input signal VIN, a second input end Vin− of the comparator is connected to the negative end VIN(−) of the analog input signal VIN, a third input end Vref+ of the comparator is connected to the i-th non-inverting reference voltage Vrefp<i>, and a fourth input end Vref− of the comparator is connected to the i-th inverting reference voltage Vrefn<i>, where i=1, 2, . . . , 2^{N}.

In one or more embodiments of the present application, 2^{N} drivers are arranged in parallel. In the i-th driver U(i)₁₃₂, a first input end A1 of the driver is connected to a first output end OP of the i-th comparator, a second input end A2 of the driver is connected to a second output end ON of the i-th comparator, and a third input end CK of the driver is connected to the first clock signal ϕ1.

In one or more embodiments of the present application, an output end of the m-th comparator U(m)₁₃₁ outputs a first initial digital signal, an output end of the m-th driver U(m)₁₃₂ outputs a first digital signal, the output end of the n-th comparator U(n)₁₃₁ outputs a second initial digital signal, and the output end of the n-th driver U(n)₁₃₂ outputs a second digital signal, where m is an odd number from 1 to 2^{N}, and n is an even number from 1 to 2^{N}. Finally, 2^{N}−1 first digital signals (i.e., first digital signals DO<2^{N}:1>) are obtained at the odd output ports of the comparator array unit 13, and 2^{N}−1 second digital signals (i.e., second digital signals DE<2^{N}:1>) are obtained at the even output ports of the comparator array unit 13, and the output first digital signals and second digital signals are controlled by the first clock signal ϕ1.

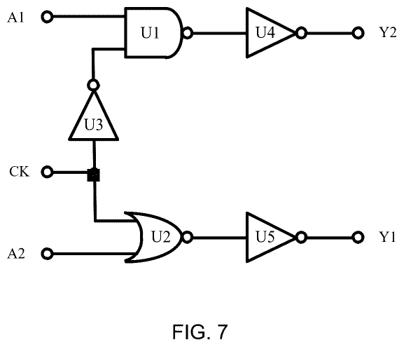

In one or more embodiments of the present application, as shown in FIG. 7, the structures of the 2^{N} drivers are the same, and each driver includes a first NAND gate U1, a first NOR gate U2, a first NOT gate U3, a second NOT gate U4, and a third NOT gate U5. A first input end of the first NAND gate U1 serves as the first input end A1 of the driver, a second input end of the first NAND gate U1 is connected to an output end of the first NOT gate U3, an output end of the first NAND gate U1 is connected to an input end of the second NOT gate U4, an output end of the second NOT gate U4 serves as a second output end Y2 of the driver, an input end of the first NOT gate U3 serves as the third input end CK of the driver, a first input end of the first NOR gate U2 is connected to an input end of the first NOT gate U3, a second input end of the first NOR gate U2 serves as the second input end A2 of the driver, the output end of the first NOR gate U2 is connected to an input end of the third NOT gate U5, and an output end of the third NOT gate U5 serves as a first output end Y1 of the driver.

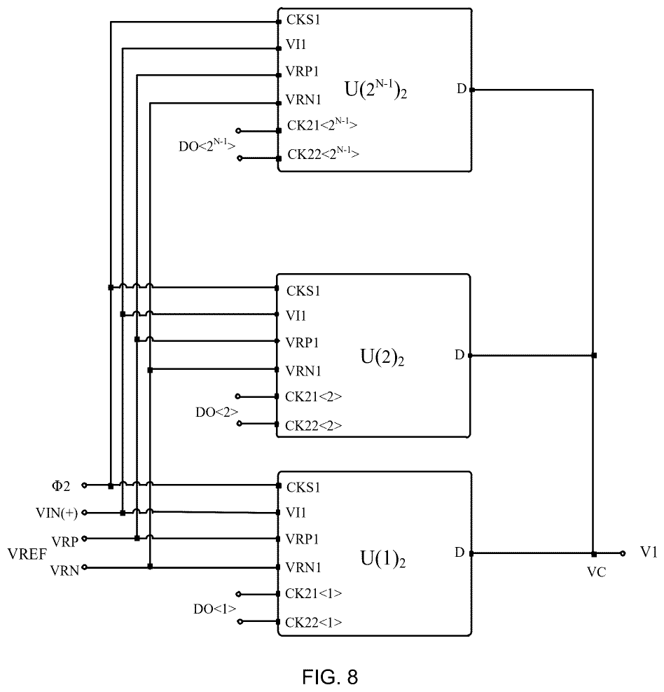

In one or more embodiments of the present application, as shown in FIG. 8, the first sub-digital-to-analog conversion module 2 includes 2^{N-1} first switched capacitor units arranged in parallel, that is, the first switched capacitor unit U(2^{N-1})₂, . . . , the first switched capacitor unit U(2)₂, and the first switched capacitor unit U(1)₂. For the j-th first switched capacitor unit U(j)₂, its first input end CKS1 is connected to a second clock signal ϕ2, its second input end VI1 is connected to the positive end VIN(+) of the analog input signal VIN, its third input end VRP1 is connected to the positive end VRP of the initial reference voltage VREF, its fourth input end VRN1 is connected to the negative end VRN of the initial reference voltage VREF, its fifth input end CK21<j> is connected to a negative end of the j-th first digital signal DO<j>, and its sixth input end CK22<j> is connected to a positive end of the j-th first digital signal DO<j>. Output ends D of the 2^{N-1} first switched capacitor units are connected in parallel and output the first analog signal V1 to the outside, where j=1, 2, . . . , 2^{N-1}.

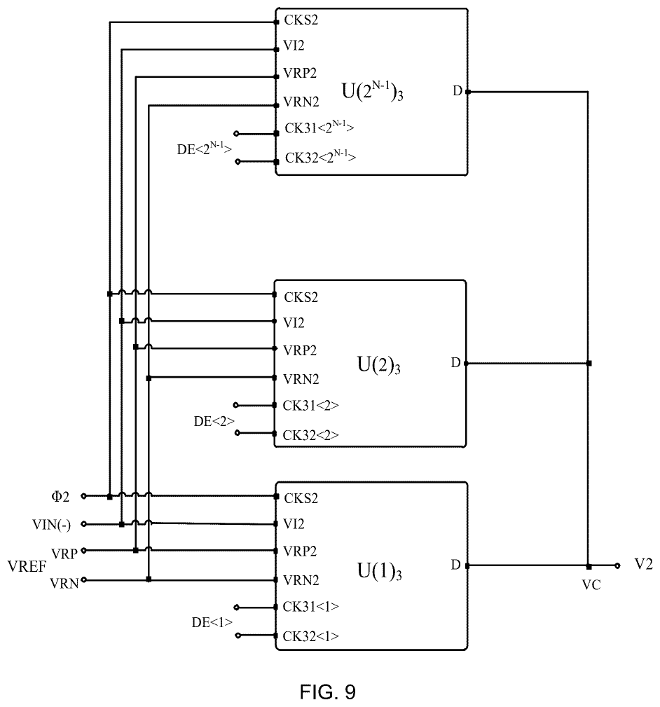

In one or more embodiments of the present application, as shown in FIG. 9, the second sub-digital-to-analog conversion module 3 includes 2^{N-1} second switched capacitor units arranged in parallel, that is, the second switched capacitor unit U(2^{N-1})₃, . . . , the second switched capacitor unit U(2)₃, and the second switched capacitor unit U(1)₃. For the j-th second switched capacitor unit U(j)₃, its first input end CKS2 is connected to the second clock signal ϕ2, its second input end VI2 is connected to the negative end VIN(−) of the analog input signal VIN, its third input end VRP2 is connected to the positive end VRP of the initial reference voltage VREF, its fourth input end VRN2 is connected to the negative end VRN of the initial reference voltage VREF, its fifth input end CK31<j> is connected to a positive end of the j-th second digital signal DE<j>, and its sixth input end CK32<j> is connected to a negative end of the j-th second digital signal DE<j>. Output ends D of the 2^{N-1} second switched capacitor units are connected in parallel and output the second analog signal V2 to the outside.

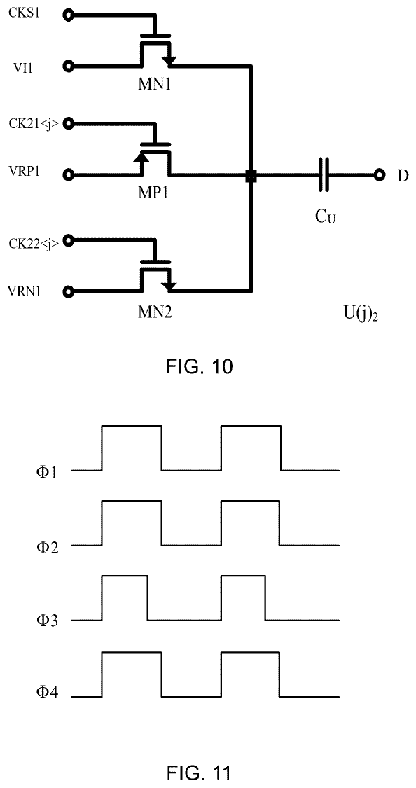

In one or more embodiments of the present application, as shown in FIG. 10, the j-th first switched capacitor unit U(j)₂ includes a first NMOS transistor MN1, a second NMOS transistor MN2, a first PMOS transistor MP1, and a switched capacitor C_{U}. The gate of the first NMOS transistor MN1 serves as the first input end CKS1 of the first switched capacitor unit U(j)₂, the drain of the first NMOS transistor MN1 serves as the second input end VI1 of the first switched capacitor unit U(j)₂, the gate of the second NMOS transistor MN2 serves as the sixth input end CK22<j> of the first switched capacitor unit U(j)₂, the drain of the second NMOS transistor MN2 serves as the fourth input end VRN1 of the first switched capacitor unit U(j)₂, the gate of the first PMOS transistor MP1 serves as the fifth input end CK21<j> of the first switched capacitor unit U(j)₂, the source of the first PMOS transistor MP1 serves as the third input end VRP1 of the first switched capacitor unit U(j)₂, the source of the first NMOS transistor MN1, the source of the second NMOS transistor MN2, and the drain of the first PMOS transistor MP1 are respectively connected to one end of the switched capacitor C_{U}, and the other end of the switched capacitor C_{U} serves as the output end D of the first switched capacitor unit U(j)₂. The structure of the second switched capacitor unit is the same as that of the first switched capacitor unit and will not be repeated here.

In one or more embodiments of the present application, as shown in FIG. 2, the switched capacitor amplification module 4 includes a third NMOS transistor N1, a fourth NMOS transistor N2, a fifth NMOS transistor N3, a sixth NMOS transistor N4, a first capacitor C_{FP}, a second capacitor C_{FN}, and a fully differential operational amplifier OTA. The gate of the third NMOS transistor N1, the gate of the fourth NMOS transistor N2, and the gate of the fifth NMOS transistor N3 are respectively connected to a third clock signal ϕ3, the drain of the third NMOS transistor N1 and the drain of the fifth NMOS transistor N3 are respectively connected to a basic signal VB, the source of the fifth NMOS transistor N3, the drain of the fourth NMOS transistor N2, a non-inverting input end IN+ of the fully differential operational amplifier OTA, the output end of the first sub-digital-to-analog conversion module 2, and one end of the first capacitor C_{FP} are connected together, the other end of the first capacitor C_{FP}, an inverting output end VO− of the fully differential operational amplifier OTA, and the drain of the sixth NMOS transistor N4 are connected together, the source of the third NMOS transistor N1, the source of the fourth NMOS transistor N2, an inverting input end IN− of the fully differential operational amplifier OTA, the output end of the second sub-digital-to-analog conversion module 3, and one end of the second capacitor C_{FN} are connected together, the other end of the second capacitor C_{FN}, a non-inverting output end VO+ of the fully differential operational amplifier OTA, and the source of the sixth NMOS transistor N4 are connected together, the gate of the sixth NMOS transistor N4 is connected to a fourth clock signal ϕ4, the non-inverting output end VO+ of the fully differential operational amplifier OTA serves as an output positive end VOUT(+) of the switched capacitor amplification module 4, and the inverting output end VO− of the fully differential operational amplifier OTA serves as an output negative end VOUT(−) of the switched capacitor amplification module 4.

The capacitance value of the first capacitor C_{FP} is equal to the capacitance value of the second capacitor C_{FN}.

In one or more embodiments of the present application, in the present application, when the pipeline stage is in the working mode, the timing state diagram of the first clock signal ϕ1, the second clock signal ϕ2, the third clock signal ϕ3, and the fourth clock signal ϕ4 is shown in FIG. 11, and the phases of the first clock signal ϕ1, the second clock signal ϕ2, the third clock signal ϕ3, and the fourth clock signal ϕ4 are the same.

In more detail, the working principle of the pipeline stage shown in FIGS. 2 to 11 is as follows.

First, when the first clock signal ϕ1, the second clock signal ϕ2, the third clock signal ϕ3, and the fourth clock signal ϕ4 are all at high levels, the first sub-digital-to-analog conversion module 2 and the second sub-digital-to-analog conversion module 3 are both in a sampling mode in which: the gate voltage of the second NMOS transistor MN2 in each first switched capacitor unit and the second switched capacitor unit is low, the second NMOS transistor MN2 is in off mode, the gate voltage of the first PMOS transistor MP1 is high, the first PMOS transistor MP1 is in off mode, the gate voltage of the first NMOS transistor MN1 is high, and the first NMOS transistor MN1 is in on mode; the gate voltage of the third NMOS transistor N1, the gate voltage of the fourth NMOS transistor N2, and the gate voltage of the fifth NMOS transistor N3 in the switched capacitor amplification module 4 are all at high levels; the switched capacitor C_{U} of each first switched capacitor unit in the first sub-digital-to-analog conversion module 2 collects the input basic signal VB at one end and collects the positive end VIN(+) of the analog input signal VIN at the other end, and the switched capacitor C_{U} of each second switched capacitor unit in the second sub-digital-to-analog conversion module 3 collects the input basic signal VB at one end and collects the negative end VIN(−) of the analog input signal VIN; the gate voltage of the sixth NMOS transistor N4 in the switched capacitor amplification module 4 is at high level, the sixth NMOS transistor N4 is turned on, and the first output end VOUT(+) and the second output end VOUT(−) of the switched capacitor amplification module 4 are short-circuited together; therefore, the output of the pipeline stage in the sampling mode is:

VOUT(+)−VOUT(−)=0 (1)

Second, when the first clock signal ϕ1, the second clock signal ϕ2, the third clock signal ϕ3, and the fourth clock signal ϕ4 are all at low levels, the first sub-digital-to-analog conversion module 2 and the second sub-digital-to-analog conversion module 3 are both in a holding mode in which: the gate voltage of the third NMOS transistor N1, the gate voltage of the fourth NMOS transistor N2, and the gate voltage of the fifth NMOS transistor N3 in the switched capacitor amplification module 4 are all at low levels, the third NMOS transistor N1, the fourth NMOS transistor N2 and the fifth NMOS transistor N3 are all turned off, and the non-inverting input end IN+ and the inverting input end IN− of the full differential operational amplifier OTA are in a high impedance state; the gate voltage of the sixth NMOS transistor N4 in the switched capacitor amplification module 4 is at a low level, and the sixth NMOS transistor N4 is turned off; the second NMOS transistor MN2 of each first switched capacitor unit in the first sub-digital-to-analog conversion module 2 is connected to the second output end Y2 of the corresponding driver in the comparator array unit 13, and the first PMOS transistor MP1 is connected to the first output end Y1 of the driver in the comparator array unit 13; the second NMOS transistor MN2 in each second switched capacitor unit in the second sub-digital-to-analog conversion module 3 is connected to the first output end Y1 of the corresponding driver in the comparator array unit 13, and the first PMOS transistor MP1 is connected to the second output end Y2 of the corresponding driver in the comparator array unit 13; in this mode, only one of the second NMOS transistor MN2 and the first PMOS transistor MP1 in each first switched capacitor unit (or second switched capacitor unit) can keep turned on, and the on and off modes are determined by the output of the corresponding comparator, and the output of the comparator is determined by the values of the analog input signal VIN and the reference voltage; according to the principle of charge conservation, the output of the pipeline stage at this time is:

$$VOUT ( + ) - VOUT ( - ) = [ \frac{{\sum }_{i = 1}^{{2}^{N - 1}} {C}_{U , 1 i}}{{C}_{FP}} VIN ( + ) - \frac{{\sum }_{i = 1}^{{2}^{N - 1}} {C}_{U , 2 i}}{{C}_{FN}} VIN ( - ) ] - [ \frac{{\sum }_{i = 1}^{{2}^{N - 1}} {D}_{i}^{+} {C}_{U , 1 i}}{{C}_{FP}} - \frac{{\sum }_{i = 1}^{{2}^{N - 1}} {D}_{i}^{-} {C}_{U , 2 i}}{{C}_{FN}} ] VREFP - [ \frac{{\sum }_{i = 1}^{{2}^{N - 1}} ( 1 - {D}_{i}^{+} ) {C}_{U , 1 i}}{{C}_{FP}} - \frac{{\sum }_{i = 1}^{{2}^{N - 1}} ( 1 - {D}_{i}^{-} ) {C}_{U , 2 i}}{{C}_{FN}} ] VREFN \qquad ( 2 )$$

In equation (2), C_{U,1i} represents the capacitance value of the switched capacitor (or sampling capacitor) C_{U} in the i-th first switched capacitor unit in the first sub-digital-to-analog conversion module, C_{U,2i} represents the capacitance value of the switched capacitor C_{U} in the i-th second switched capacitor unit in the second sub-digital-to-analog conversion module, Dᵢ⁺=1 represents that the switched capacitor C_{U} in the i-th first switched capacitor unit in the first sub-digital-to-analog conversion module is connected to VRP (i.e., VREFP), Dᵢ⁺=0 represents that the switched capacitor C_{U} in the i-th first switched capacitor unit in the first sub-digital-to-analog conversion module is connected to VRN (i.e., VREFN), Dᵢ⁻=1 represents that the switched capacitor C_{U} in the i-th second switched capacitor unit in the second sub-digital-to-analog conversion module is connected to VRP, and Dᵢ⁻=0 represents that the switched capacitor C_{U} in the i-th second switched capacitor unit in the second sub-digital-to-analog conversion module is connected to VRN.

Under ideal conditions, C_{U,1i}=C_{U,2i}=C_{FP}=C_{FN}, and equation (2) is simplified to:

$$VOUT ( + ) - VOUT ( - ) = {2}^{N - 1} [ VIN ( + ) - VINA ( - ) ] - [ {\sum }_{i = 1}^{{2}^{N - 1}} {D}_{i}^{+} - {\sum }_{i = 1}^{{2}^{N - 1}} {D}_{i}^{-} ] VREFP - [ {\sum }_{i = 1}^{{2}^{N - 1}} ( 1 - {D}_{i}^{+} ) - {\sum }_{i = 1}^{{2}^{N - 1}} ( 1 - {D}_{i}^{-} ) ] VREFN \qquad ( 3 )$$

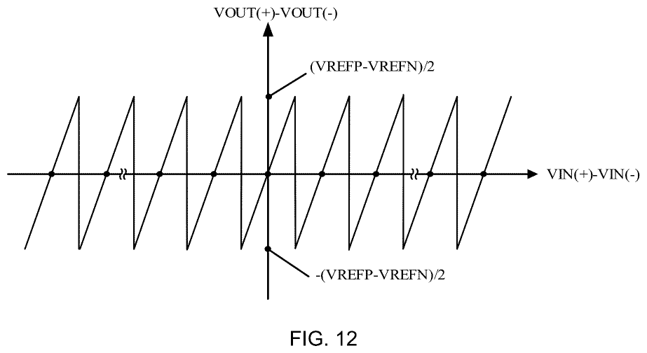

According to equation (3), in the pipelined analog-to-digital converter provided by the present application, based on the pipeline structure shown in FIG. 2, a residual signal amplification with a gain of 2N−1 is achieved, and its corresponding transmission curve is shown in FIG. 12.

In conclusion, in the pipelined analog-to-digital converter provided by the present application, at least one pipeline stage is based on the structure of “N-bit sub-analog-to-digital conversion module+first sub-digital-to-analog conversion module+second sub-digital-to-analog conversion module+switched capacitor amplification module”, the first sub-digital-to-analog conversion module and the second sub-digital-to-analog conversion module respectively receive and process 2^{N-1} digital signals, that is, the output of the odd-numbered comparison drive structure and the output of the even-numbered comparison drive structure in the N-bit sub-analog-to-digital conversion module respectively control the first sub-digital-to-analog conversion module and the second sub-digital-to-analog conversion module, correspondingly requiring 2*2^{N-1} switched capacitors, while for the pipeline stage based on the structure of “N-bit sub-analog-to-digital conversion module+sub-digital-to-analog conversion module+subtractor+multiplier”, the non-inverting input and the inverting input of the differential input comparison is completely symmetrical, correspondingly requiring 2*2^{N} switched capacitors. Compared with the pipeline stage based on the structure of “N-bit sub-analog-to-digital conversion module+sub-digital-to-analog conversion module+subtractor+multiplier”, the number of sub-digital-to-analog conversion switched capacitors in the pipeline stage of the present application is reduced by 50%, the corresponding power consumption is reduced by 50%, and the processing speed is increased by 1-2 times. Therefore, the present application can effectively reduce the number of sub-digital-to-analog conversion switched capacitors in the pipeline stage, reduce the area of the switched capacitor array, reduce the power consumption of the switched capacitor array, and improve the processing speed of the pipeline stage.

As stated above, the pipelined analog-to-digital converter provided by the present application may have at least one of the following beneficial effects.

In a pipelined analog-to-digital converter, at least one pipeline stage is based on the structure of “N-bit sub-analog-to-digital conversion module+first sub-digital-to-analog conversion module+second sub-digital-to-analog conversion module+switched capacitor amplification module”, the first sub-digital-to-analog conversion module and the second sub-digital-to-analog conversion module respectively receive and process 2^{N-1} digital signals, correspondingly requiring 2*2^{N-1} switched capacitors, while for the pipeline stage based on the structure of “N-bit sub-analog-to-digital conversion module+sub-digital-to-analog conversion module+subtractor+multiplier”, the non-inverting input and the inverting input of its differential input comparison are completely symmetrical, correspondingly requiring 2*2^{N} switched capacitors. Therefore, compared with the pipeline stage of above structure of “N-bit sub-analog-to-digital conversion module+sub-digital-to-analog conversion module+subtractor+multiplier”, the pipelined analog-to-digital converter in present application may effectively reduce the number of sub-digital-to-analog conversion switched capacitors of the pipeline stage, reduce the area of the switched capacitor array, reduce the power consumption of the switched capacitor array, and improve the processing speed of the pipeline stage.

The above embodiments are merely illustrative of the principles and effects of the present application and are not intended to limit the present application. Anyone familiar with the art may modify or alter the above embodiments without departing from the spirit and scope of the present application. Therefore, all equivalent modifications or alterations made by a person of ordinary skill in the art without departing from the spirit and technical concept disclosed by the present application shall still be covered by the claims of the present application.

What is claimed is:

1. A pipelined analog-to-digital converter, comprising a plurality of pipeline stages cascaded in sequence, wherein at least one of the pipeline stages comprises:
a N-bit sub-analog-to-digital conversion module configured to receive an analog input signal and perform analog-to-digital conversion on the analog input signal to obtain and output 2^{N} digital signals;
a first sub-digital-to-analog conversion module configured to receive 2^{N-1} digital signals and perform digital-to-analog conversion on the 2^{N-1} digital signals to obtain and output a first analog signal;
a second sub-digital-to-analog conversion module configured to receive other 2^{N-1} digital signals and perform digital-to-analog conversion on the other 2^{N-1} digital signals to obtain and output a second analog signal; and
a switched capacitor amplification module configured to receive the first analog signal and the second analog signal, perform a difference operation on the first analog signal and the second analog signal, and perform an amplification operation on a result of the difference operation, to obtain and output an analog output signal, and
wherein N is an integer greater than or equal to 1.

2. The pipelined analog-to-digital converter according to claim 1, wherein the N-bit sub-analog-to-digital conversion module comprises:
a first resistor divider unit configured to perform voltage division processing on an initial reference voltage and output 2^{N} non-inverting reference voltages to outside;
a second resistor divider unit configured to perform voltage division processing on the initial reference voltage and output 2^{N} inverting reference voltages to the outside; and
a comparator array unit connected to the first resistor divider unit and the second resistor divider unit respectively, the comparator array unit configured to receive the analog input signal and compare the analog input signal with 2^{N} reference voltages, respectively, to obtain the 2^{N} digital signals, wherein the 2^{N} digital signals comprise 2^{N-1} first digital signals and 2^{N-1} second digital signals, and the 2^{N} non-inverting reference voltages correspond one-to-one to the 2^{N} inverting reference voltages to constitute the 2^{N} reference voltages.

3. The pipelined analog-to-digital converter according to claim 1, wherein
the switched capacitor amplification module comprises a third NMOS transistor, a fourth NMOS transistor, a fifth NMOS transistor, a sixth NMOS transistor, a first capacitor, a second capacitor, and a fully differential operational amplifier,
a gate of the third NMOS transistor, a gate of the fourth NMOS transistor, and a gate of the fifth NMOS transistor are respectively connected to a third clock signal,
a drain of the third NMOS transistor and a drain of the fifth NMOS transistor are respectively connected to a basic signal,
a source of the fifth NMOS transistor, a drain of the fourth NMOS transistor, a non-inverting input end of the fully differential operational amplifier, an output end of the first sub-digital-to-analog conversion module, and a first end of the first capacitor are connected together, a second end of the first capacitor, an inverting output end of the fully differential operational amplifier, and a drain of the sixth NMOS transistor are connected together,
a source of the third NMOS transistor, a source of the fourth NMOS transistor, an inverting input end of the fully differential operational amplifier, an output end of the second sub-digital-to-analog conversion module, and a end of the second capacitor are connected together, a second end of the second capacitor, a non-inverting output end of the fully differential operational amplifier, and a source of the sixth NMOS transistor are connected together, and
a gate of the sixth NMOS transistor is connected to a fourth clock signal, the non-inverting output end of the fully differential operational amplifier serves as a positive output end of the switched capacitor amplification module, and the inverting output end of the fully differential operational amplifier serves as a negative output end of the switched capacitor amplification module.

4. The pipelined analog-to-digital converter according to claim 2, wherein
the first resistor divider unit comprises a first input port, a second input port, and 2^{N}+1 first resistors, and
the 2^{N}+1 first resistors are connected in series between the first input port and the second input port in sequence, the first input port is connected to a positive end of the initial reference voltage, the second input port is connected to a negative end of the initial reference voltage, and each common end of each two adjacent first resistors outputs the non-inverting reference voltage.

5. The pipelined analog-to-digital converter according to claim 2, wherein
the second resistor divider unit comprises a third input port, a fourth input port, and 2^{N}+1 second resistors, and
the 2^{N}+1 second resistors are connected in series between the third input port and the fourth input port in sequence, the third input port is connected to a negative end of the initial reference voltage, the fourth input port is connected to a positive end of the initial reference voltage, and each common end of each two adjacent second resistors outputs the inverting reference voltage.

6. The pipelined analog-to-digital converter according to claim 5, wherein the comparator array unit comprises:
2^{N} comparators configured to compare and quantize the analog input signal with the 2^{N} reference voltages one by one and output 2^{N}−1 first initial digital signals and 2^{N}−1 second initial digital signals; and
2^{N} drivers, wherein input ends of the 2^{N} drivers are connected to output ends of the 2^{N} comparators in a one-to-one correspondence, and output ends of the 2^{N} drivers output the 2^{N}−1 first digital signals and the 2^{N}−1 second digital signals controlled by a first clock signal.

7. The pipelined analog-to-digital converter according to claim 6, wherein
the 2^{N} comparators are arranged in parallel; in an i-th comparator, a first input end of the i-th comparator is connected to a positive end of the analog input signal, a second input end of the i-th comparator is connected to a negative end of the analog input signal, a third input end of the i-th comparator is connected to an i-th non-inverting reference voltage, and a fourth input end of the i-th comparator is connected to an i-th inverting reference voltage, wherein i=1, 2, . . . , 2^{N};
the 2^{N} drivers are arranged in parallel; in an i-th said driver, a first input end of the i-th driver is connected to a first output end of the i-th comparator, a second input end of the i-th driver is connected to a second output end of the i-th comparator, and a third input end of the i-th driver is connected to the first clock signal; and
an output end of an m-th comparator outputs the first initial digital signal, an output end of an m-th driver outputs the first digital signal, an output end of an n-th comparator outputs the second initial digital signal, and an output end of an n-th driver outputs the second digital signal, wherein m is an odd number from 1 to 2^{N}, and n is an even number from 1 to 2^{N}.

8. The pipelined analog-to-digital converter according to claim 7, wherein
the driver comprises a first NAND gate, a first NOR gate, a first NOT gate, a second NOT gate, and a third NOT gate, and
a first input end of the first NAND gate serves as a first input end of the driver, a second input end of the first NAND gate is connected to an output end of the first NOT gate, an output end of the first NAND gate is connected to an input end of the second NOT gate, an output end of the second NOT gate serves as a second output end of the driver, an input end of the first NOT gate serves as a third input end of the driver, a first input end of the first NOR gate is connected to the input end of the first NOT gate, a second input end of the first NOR gate serves as a second input end of the driver, an output end of the first NOR gate is connected to an input end of the third NOT gate, and an output end of the third NOT gate serves as a first output end of the driver.

9. The pipelined analog-to-digital converter according to claim 7, wherein
the first sub-digital-to-analog conversion module comprises 2^{N-1} first switched capacitor units arranged in parallel, a first input end of a j-th first switched capacitor unit is connected to a second clock signal, a second input end of the j-th first switched capacitor unit is connected to the positive end of the analog input signal, a third input end of the j-th first switched capacitor unit is connected to the positive end of the initial reference voltage, a fourth input end of the j-th first switched capacitor unit is connected to the negative end of the initial reference voltage, a fifth input end of the j-th first switched capacitor unit is connected to a negative end of a j-th first digital signal, a sixth input end of the j-th first switched capacitor unit is connected to a positive end of the j-th first digital signal, and output ends of the 2^{N-1} first switched capacitor units are connected in parallel and output the first analog signal to the outside, wherein j=1, 2, . . . , 2^{N-1}; and
the second sub-digital-to-analog conversion module comprises 2^{N-1} second switched capacitor units arranged in parallel, a first input end of a j-th second switched capacitor unit is connected to the second clock signal, a second input end of the j-th second switched capacitor unit is connected to the negative end of the analog input signal, a third input end of the j-th second switched capacitor unit is connected to the positive end of the initial reference voltage, a fourth input end of the j-th second switched capacitor unit is connected to the negative end of the initial reference voltage, a fifth input end of the j-th second switched capacitor unit is connected to a positive end of a j-th second digital signal, a sixth input end of the j-th second switched capacitor unit is connected to a negative end of the j-th second digital signal, and output ends of the 2^{N-1} second switched capacitor units are connected in parallel and output the second analog signal to the outside.

10. The pipelined analog-to-digital converter according to claim 9, wherein
the first switched capacitor unit comprises a first NMOS transistor, a second NMOS transistor, a first PMOS transistor, and a switched capacitor, and
a gate of the first NMOS transistor serves as a first input end of the first switched capacitor unit, a drain of the first NMOS transistor serves as a second input end of the first switched capacitor unit, a gate of the second NMOS transistor serves as a sixth input end of the first switched capacitor unit, a drain of the second NMOS transistor serves as a fourth input end of the first switched capacitor unit, a gate of the first PMOS transistor serves as a fifth input end of the first switched capacitor unit, a source of the first PMOS transistor serves as a third input end of the first switched capacitor unit, a source of the first NMOS transistor, a source of the second NMOS transistor, and a drain of the first PMOS transistor are respectively connected to a first end of the switched capacitor, and a second end of the switched capacitor serves as an output end of the first switched capacitor unit.

11. The pipelined analog-to-digital converter according to claim 10, wherein
the switched capacitor amplification module comprises a third NMOS transistor, a fourth NMOS transistor, a fifth NMOS transistor, a sixth NMOS transistor, a first capacitor, a second capacitor, and a fully differential operational amplifier,
a gate of the third NMOS transistor, a gate of the fourth NMOS transistor, and a gate of the fifth NMOS transistor are respectively connected to a third clock signal,
a drain of the third NMOS transistor and a drain of the fifth NMOS transistor are respectively connected to a basic signal,
a source of the fifth NMOS transistor, a drain of the fourth NMOS transistor, a non-inverting input end of the fully differential operational amplifier, an output end of the first sub-digital-to-analog conversion module, and a first end of the first capacitor are connected together, a second end of the first capacitor, an inverting output end of the fully differential operational amplifier, and a drain of the sixth NMOS transistor are connected together,
a source of the third NMOS transistor, a source of the fourth NMOS transistor, an inverting input end of the fully differential operational amplifier, an output end of the second sub-digital-to-analog conversion module, and a first end of the second capacitor are connected together, a second end of the second capacitor, a non-inverting output end of the fully differential operational amplifier, and a source of the sixth NMOS transistor are connected together, and
a gate of the sixth NMOS transistor is connected to a fourth clock signal, the non-inverting output end of the fully differential operational amplifier serves as a positive output end of the switched capacitor amplification module, and the inverting output end of the fully differential operational amplifier serves as a negative output end of the switched capacitor amplification module.

12. The pipelined analog-to-digital converter according to claim 11, wherein a capacitance value of the first capacitor is equal to a capacitance value of the second capacitor.
